(19) United States
(12) Patent Application Publication
(10) Pub. No.: US 2007/0230147 A1
(43) Pub. Date: Oct. 4, 2007

(54) Circuit board and electronic apparatus having the same

(75) Inventor: Jin Abe, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/589,093

(22) Filed: Oct. 30, 2006

(30) Foreign Application Priority Data
Mar. 29, 2006 (JP) 2006-089717

(51) Int. Cl. H05K 7/12; H05K 7/10

(52) U.S. Cl. 361/767

(57) ABSTRACT

A circuit board having a mount part onto which the electronic component is mounted includes a plurality of wiring patterns at least one of which is electrically connectible to one of a plurality of first terminals of an electronic component, the plurality of first terminals being hidden by the electronic component once the electronic component is mounted onto the mount part, a pair of second terminals that expose around a mount part, one of the pair of second terminals being one-by-one connected to each first terminal, the other of the pair of second terminals being connected to each wiring pattern, and a signal line that exposes around the mount part and electrically connects the pair of second terminals to each other.

This application claims the right of foreign priority under 35 U.S.C. §119 based on Japanese Patent Application No. 2006-089717, filed on Mar. 29, 2006, which is hereby incorporated by reference herein in its entirety as if fully set forth herein.

### BACKGROUND OF THE INVENTION

The present invention relates generally to a circuit board, and more particularly to a circuit board that has a terminal connectible to an electronic component on a mount part onto which the electronic component is mounted, the terminal being hidden and invisible after the electronic component is mounted. The present invention is suitable, for example, for a structure of a printed board to which an LSI chip and various packages, such as a ball grid array (“BGA”) and a land grid array (“LGA”), can be attached.

Recently, a demand for providing an electronic apparatus that realizes high-density mounting and has excellent maintainability has increasingly grown. A BGA package has been conventionally proposed to meet the demand for the high-density mounting. The BGA package is mounted with an IC or LSI chip that generally serves as a CPU, and the BGA package is one type of a package board soldered to a printed board (also referred to as a “system board” or “motherboard”). The BGA package realizes the high density through a narrower pitch and more pins (i.e., high-density leads).

Referring now to FIGS. 7 and 8, a description will be given of the conventional printed board 20 mounted with a BGA package 10. Here, FIG. 7 is a schematic plane view of the printed board 20 mounted with the BGA package 10, and transmits part of the BGA package 10 and the printed board 20. FIG. 8 is a schematic partial sectional view of FIG. 7, and omits components other than two pads 22 in plural pads 22, and patterns other than two wiring patterns 24 in plural wiring patterns 24.

As shown in FIGS. 7 and 8, the BGA package 10 seals a chip 14 on a substrate 12 with resin 16, and is connected to the pads 22 on the circuit board 20 via bumps (or bump balls) 18. In FIG. 7, the BGA package 10 is connected to the pads 22 on the printed board 20 via the bumps 18. The pads 22 are connected to the wiring patterns 24 provided around a package mount part. For the improved maintainability, a configuration needs to facilitate a test of the BGA package 10 and a modification of the wiring pattern 24.

Prior art include, for example, Japanese Utility-Model Application, Publication No. 5-53263, and Japanese Patent Applications, Publication Nos. 8-70024 and 10-199941.

The test of the BGA package 10, such as a waveform measurement, the test of the wiring pattern 24, such as a logic confirmation, and the modification of the wiring pattern 24 require a connection between a measuring apparatus, such as a probe and an oscilloscope, and the bump 18, the wiring pattern 24 or a signal line (or a wire including a power supply line) connected to the bump 18 or the wiring pattern 24. However, the bumps 18 and the pads 22 are hidden by the BGA package 10 once the BGA package 10 is mounted. In addition, each wiring pattern 24 is often connected directly to the pad through an internal layer of the printed board 20. In this way, the bump 18 and the wiring pattern 24 are often so invisible that it is difficult to connect them with the measuring apparatus. In this regard, it is conceivable to provide an exposing terminal on the circuit board, such as a throughput and a pad, which is connected to the signal line. However, the modification of the wiring pattern 24 is difficult only with this terminal, for example, in an attempt to provide a new wiring pattern 24 by cutting the previous wiring pattern 24.

### BRIEF SUMMARY OF THE INVENTION

Accordingly, it is an exemplified object of the present invention to provide a circuit board having excellent maintainability, and an electronic apparatus having the same.

A circuit board according to one aspect of the present invention having a mount part onto which the electronic component is mounted includes a plurality of wiring patterns at least one of which is electrically connectible to one of a plurality of first terminals of an electronic component, the plurality of first terminals being hidden by the electronic component once the electronic component is mounted onto the mount part, a pair of second terminals that expose around a mount part, one of the pair of second terminals being one-by-one connected to each first terminal, the other of the pair of second terminals being connected to each wiring pattern, and a signal line that exposes around the mount part and electrically connects the pair of second terminals to each other. The pair of second terminals and the signal line expose. Although the first terminals are hidden by the electronic component and the wiring pattern does not expose to the outside, the circuit board uses the pair of second terminals and the signal line, and enables waveform of the electronic apparatus to be measured and the wiring pattern to be modified. For example, since the second terminals are one-by-one correspondence to each first terminal, a test of the electronic apparatus can be performed by using the second terminals. In modifying the wiring pattern, the signal line may be cut or the modified wiring pattern may be connected to the second terminal closer to the first terminal without cutting the signal line. A variety of tests can be performed when the signal line is grasped by and connected to a probe, or when one of the second terminals is connected to the measuring apparatus.

The second terminal may be a throughhole or a pad (soldering layer). The electronic component is, for example, a semiconductor package, such as a BGA package. The signal line may be uncoated or coating may be made removable. Thereby, the signal line is connectible to the probe. The circuit board mounted with the electronic component, an electronic apparatus including the above circuit board, and a method for measuring the electronic component and modifying the wiring pattern using the above circuit board constitute one aspect of the present invention.

The plurality of first terminals may be arranged in a matrix on the mount part, and the signal line may be arranged in a single stage or multistage manner around the mount part parallel to a direction of a row or column of the first terminals. The multistage arrangement can allow an increase of the number of first terminals.

Preferably, a length of the signal line is 1.5 mm or longer, and a distance between the mount part and the terminal farthest from the mount part is 10 mm or shorter. A signal line of 1.5 mm or longer can be easily grasped by the probe. The distance of 10 mm or smaller prevents a significant reduction of the electronic-component mountable area. An interval between two adjacent signal lines may be preferably 1.5 mm or longer, because the signal line can be easily grasped by the probe.

The circuit board may further include a jumper pin provided at one of the pair of second terminals, thereby improving the operability of the waveform measurement by an oscilloscope. The circuit board may further include a connector connected to the plural second terminals. The connector having several tens of pins to several hundred pins improves a measurement operability of a measuring apparatus.

Other objects and further features of the present invention will become readily apparent from the following description of preferred embodiments with reference to the accompanying drawings.

### BRIEF DESCRIPTION OF THE DRAWINGS

FIG. 1 is a schematic perspective view of an electronic apparatus according to the present invention.

FIG. 2 is a schematic plane view of a printed board mounted with the electronic apparatus shown in FIG. 1.

FIG. 3 is a schematic partial sectional view of the printed board shown in FIG. 2.

FIG. 4 is a schematic plane view of a variation shown in FIG. 2.

FIG. 5 is a schematic plane view of another variation shown in FIG. 2.

FIG. 6 is a schematic plane view of another variation shown in FIG. 2.

FIG. 7 is a schematic transparent plane view of a conventional printed board.

FIG. 8 is a schematic partial sectional view of the printed board shown in FIG. 7.

### DETAILED DESCRIPTION OF THE PREFERRED EMBODIMENTS

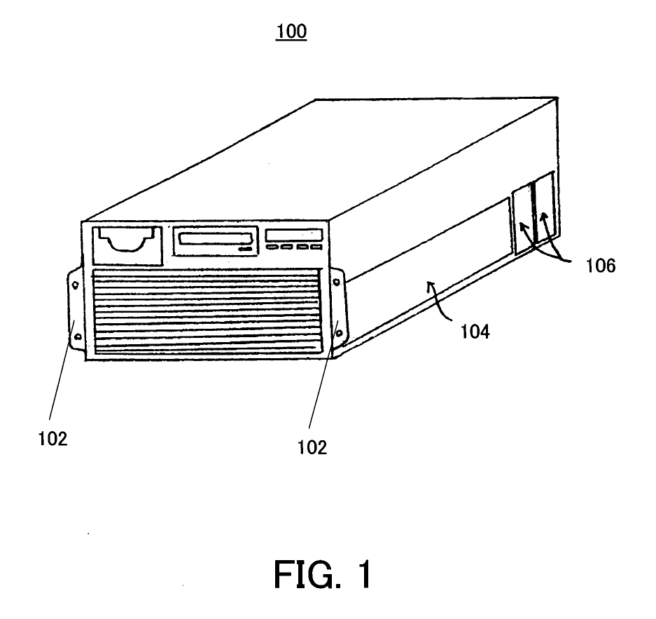

Referring now to the accompanying drawings, a description will be given of an electronic apparatus 100 according to one embodiment of the present invention. Here, FIG. 1 is a schematic perspective view of the electronic apparatus 100. As shown in FIG. 1, the electronic apparatus 100 is illustratively implemented as a rack mount type UNIX server. The electronic apparatus 100 is screwed onto a rack (not shown) by a pair of brackets 102, and includes a printed board 110 in a housing 104. Fan modules 106 are provided to the housing 104. The fan module 106 rotates a built-in cooling fan to generate the airflow, and compulsorily cools a heat sink in the housing 104.

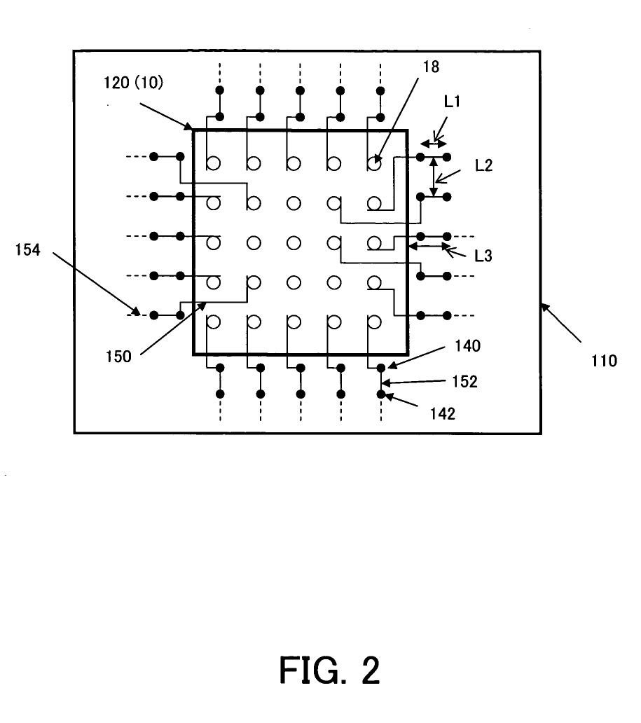

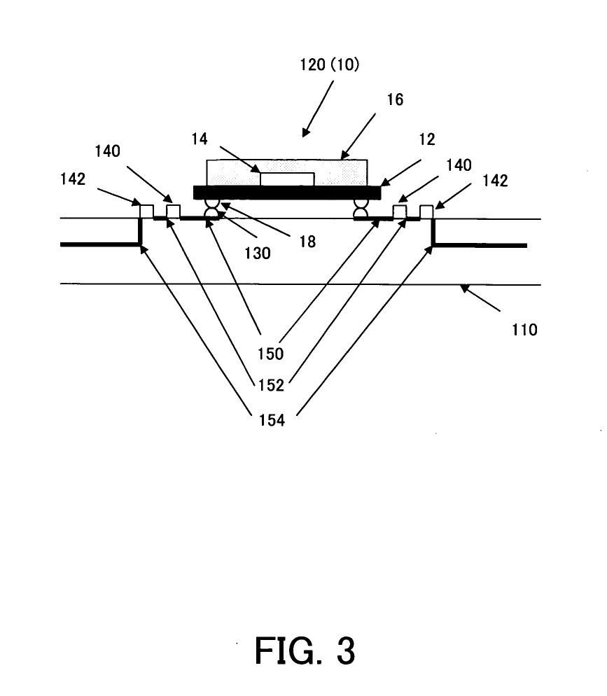

The printed board 110 includes a semiconductor package (electronic component) 120, plural block plates (not shown) in which a memory card is to be inserted, and a connector (not shown) with an external apparatus, such as a HDD and a LAN. FIG. 2 is a schematic plane view of the printed board 110, and omits components other than the semiconductor package 120 and its peripheral circuits. FIG. 3 is a schematic partial sectional view of FIG. 2, and omits components other than two pads 130 in plural pads 130 and two wiring patterns 154 in plural wiring patterns 154.

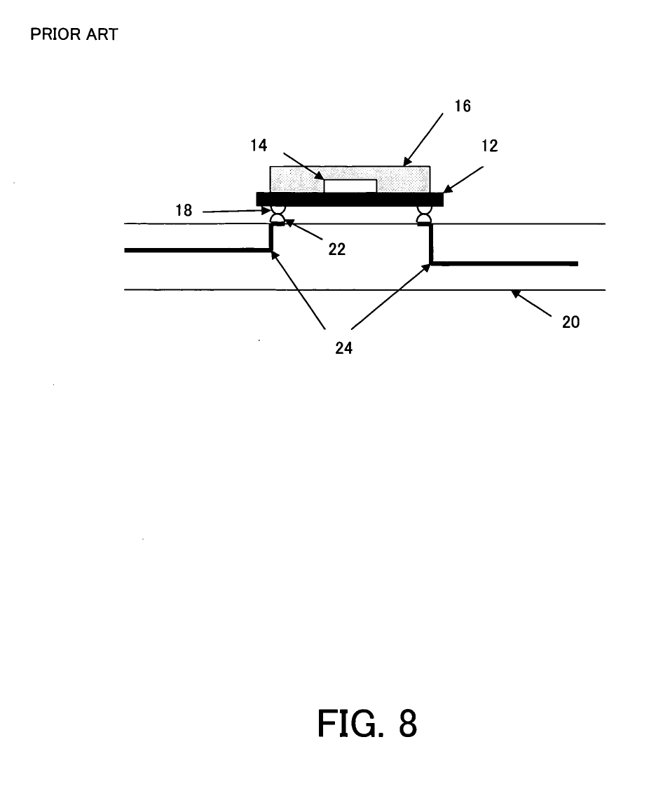

The semiconductor package 120, like a BGA and a LGA, may be one that makes hidden plural pads that are electrically connectible to the semiconductor package 120 once the semiconductor package 120 is mounted. In this embodiment, the semiconductor package 120 is the BGA package. The BGA package is similar to the BGA package 10 shown in FIG. 8 in that the BGA package 120 seals the chip 14 on the substrate 12 with resin 16, and is connected to the pads 22 on the circuit board 20 via bumps (or bump balls) (first terminal) 18.

The printed board 110 includes plural pads 130, plural pairs of terminals (second terminals) 140 and 142, signal lines 150 and 152, and wiring patterns 154.

The pad 130 is electrically connected to the semiconductor package 120. The pad 130 is hidden by the semiconductor package 120 shown by a wide square line in FIG. 2 once the semiconductor package 120 is mounted. The wide line in FIG. 2 represents a mount part onto which the semiconductor package 120 is mounted.

Among the plural pairs of terminals 140 and 142, the terminal 140 is connected to the pad 130 and the terminal 142 is connected to the wiring pattern 154. The terminals 140 and 142 are, for example, a throughhole or a pad (soldering layer). A length L3 between the mount part and the terminal 142 farthest from the mount part is preferably 10 mm or shorter so as not to remarkably reduce the electronic-component mountable area. Thus, terminals necessary for a waveform measurement and a (wiring) modification among the bumps 18 are taken out as throughholes for one-by-one connections having a small distance with the bumps 18 around the semiconductor package 120. The terminal 142 is connected to a necessary signal line by a single connection or multiple connections.

The signal line 150 connects the pad 130 to the terminal 140.

The signal line 152 exposes around the mount part, and connects the pair of terminals 140 and 142 to each other. The signal line 152 may be uncoated, or the coating of the signal line 152 may be made removable. Thereby, the signal line 152 is connectable with a measuring apparatus, such as a probe. A length L1 of the signal line 152 is 1.5 mm or longer. 1.5 mm is the minimum width for the signal line's probe contact or pattern cutting. In addition, an interval L2 of two adjacent signal lines 152 is preferably 1.5 mm or longer. When the interval between the two signal lines is 1.5 mm or longer, the probe can easily grasp the signal line 152. This embodiment sets both L1 and L2 to about 2 mm.

The wiring pattern 154 may be a signal line, and is connected to the pad 130 and constitute a predetermined logic circuit. As described above, the wiring pattern 154 is arranged in the internal layer of the printed board 110, and often invisible from the outside.

Each pair of terminals 140 and 142 and the signal line 152 expose. Thereby, although the pad 130 is hidden by the semiconductor package 120 and the wiring pattern 154 does not expose to the outside, the printed board 110 uses each pair of terminals 140 and 142 and the signal line 152, and enables the semiconductor package 120 to be tested and the wiring pattern 154 to be modified. For example, since the terminals 140 and 142 are one-by-one correspondence to each bump 18, a test of the semiconductor package 120, such as a waveform measurement, can be performed by using the terminals 140 and 142. In modifying the wiring pattern 154, the signal line 152 may be cut or the modified wiring pattern may be connected to the terminal 140 without cutting the signal line 152. A variety of tests can be performed when the signal line 152 is grasped by and connected to the probe, or when one of the terminals 140 and 142 is connected to the measuring apparatus.

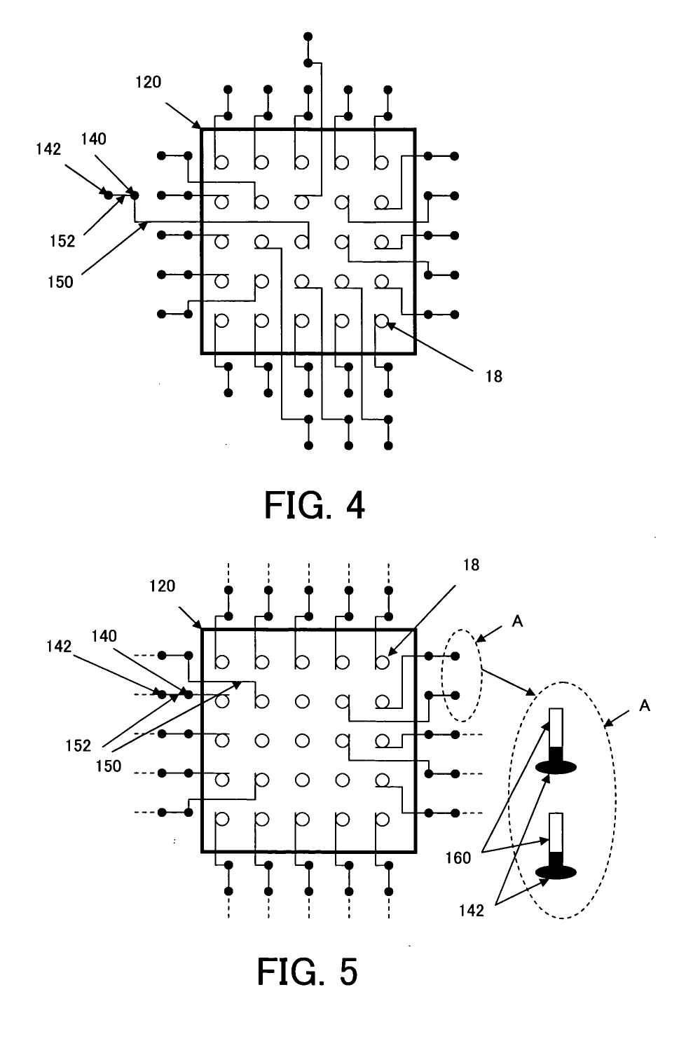

Plural bumps 18 are arranged in a matrix on the mount part, and a single stage or multistage signal lines 152 can be arranged around the mount part parallel to the row or column of the bumps 18. FIG. 2 shows a single stage of signal lines 152, whereas FIG. 4 shows multistage signal lines 152. The multistage arrangement can allow an increase of the number of bumps 18. Here, FIG. 4 is a schematic plane view of a variation of FIG. 2.

As shown in FIG. 5, when the terminal 140 or 142 is provided with a jumper pin 160, the operability of the waveform measurement by an oscilloscope improves. Here, FIG. 5 is a schematic plane view of another variation of FIG. 2. FIG. 5 shows an embodiment that provides the jumper pin 160 to the terminal 142, enlarging an A part.

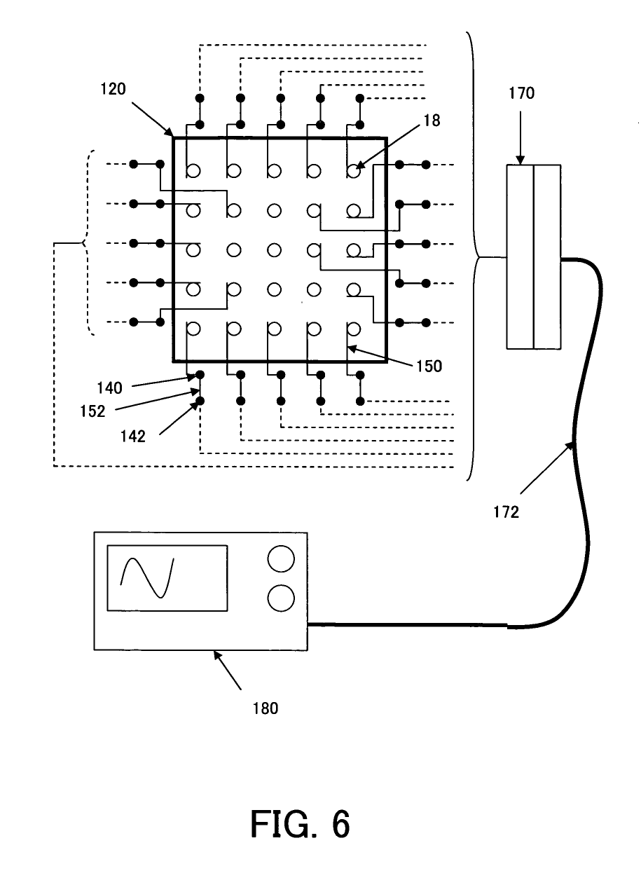

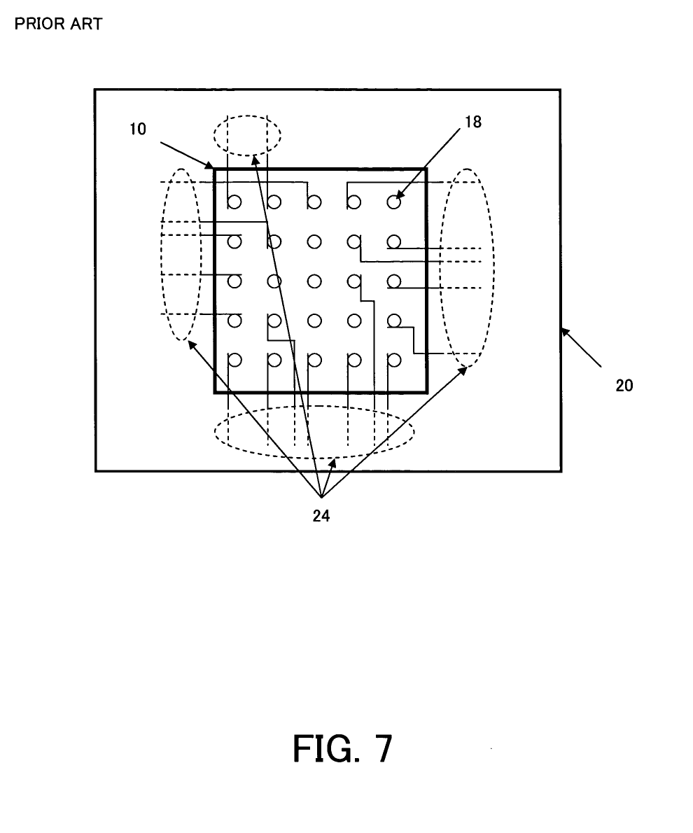

When a connector 170 is connected to the terminals 142 and provided with several tens of pins to several hundred pins as shown in FIG. 6, a measurement operability of a measuring apparatus 180 improves, such as an oscilloscope and a logic analyzer. Thereby, the waveform can be measured and the logic can be confirmed. 172 denotes a connector-cum cable. Here, FIG. 6 shows a connection illustration between the connector 170 and the terminals 142.

Further, the present invention is not limited to these preferred embodiments, and various variations and modifications may be made without departing from the scope of the present invention.

Thus, the present invention can provide a circuit board having excellent maintainability, and an electronic apparatus having the same.

What is claimed is:

1. A circuit board having a mount part onto which the electronic component is mounted, said circuit board comprising:
a plurality of wiring patterns at least one of which is electrically connectible to one of a plurality of first terminals of an electronic component, the plurality of first terminals being hidden by the electronic component once the electronic component is mounted onto the mount part;
a pair of second terminals that expose around a mount part, one of the pair of second terminals being one-by-one connected to each first terminal, the other of the pair of second terminals being connected to each wiring pattern; and
a signal line that exposes around the mount part and electrically connects the pair of second terminals to each other.

2. A circuit board according to claim 1, wherein the plurality of first terminals are arranged in a matrix on the mount part, and the signal line is arranged in a single stage or multistage manner around the mount part parallel to a direction of a row or column of the first terminals.

3. A circuit board according to claim 1, wherein a length of the signal line is 1.5 mm or longer, and a distance between the mount part and the terminal farthest from the mount part is 10 mm or shorter.

4. A circuit board according to claim 1, wherein an interval between two adjacent signal lines is 1.5 mm or longer.

5. A circuit board according to claim 1, wherein the second terminal is a throughhole or a pad.

6. A circuit board according to claim 1, further comprising a jumper pin provided at one of the pair of second terminals.

7. A circuit board according to claim 1, further comprising a connector connected to the plural second terminals.

8. A circuit board according to claim 1, wherein the electronic component is a semiconductor package.

9. A circuit board according to claim 1, wherein the signal line is uncoated.

10. A circuit board according to claim 1, further comprising the electronic component.

11. An electronic apparatus comprising a circuit board according to claim 1.

12. A method for measuring the electronic component and modifying the wiring pattern using a circuit board according to claim 1.
